(19) United States
(12) Patent Application Publication
(10) Pub. No.: US 2023/0223252 A1
(43) Pub. Date: Jul. 13, 2023

(54) METHOD, SEMICONDUCTOR STRUCTURE, AND VACUUM PROCESSING SYSTEM

(71) Applicant: Turun yliopisto, Turun yliopisto (FI)

(72) Inventors: Pekka Laukkanen, Turku (FI); Zahra Jahanshah Rad, Turku (FI); Juha-Pekka Lehtiö, Turku (FI); Mikhail Kuzmin, St. Petersburg (RU); Marko Punkkinen, Turku (FI); Kalevi Kokko, Turku (FI)

(21) Appl. No.: 17/995,078

(22) PCT Filed: Mar. 29, 2021
(86) PCT No.: PCT/FI2021/050220

§ 371 Date: Sep. 29, 2022

(30) Foreign Application Priority Data
Mar. 30, 2020 (FI) 20205316

(51) Int. Cl. H01L 21/02; H01L 21/67; H01L 31/18; C23C 16/455; C23C 16/56; C23C 16/40

(52) U.S. Cl. CPC H01L 21/02356; H01L 21/02337; H01L 21/67098; H01L 31/1868; C23C 16/45525; C23C 16/56; C23C 16/401; H01L 21/02238; H01L 21/02255; H01L 21/02164; H01L 21/02271; H01L 21/0228

(57) ABSTRACT

This disclosure relates to a method (100) for passivating a semiconductor structure, comprising a semiconductor layer and an oxide layer on the semiconductor layer; a semiconductor structure; and a vacuum processing system. The method (100) comprises providing the semiconductor structure (110) in a vacuum chamber (310) and, while keeping the semiconductor structure in the vacuum chamber (120) throughout a refinement period with a duration of at least 25 s refining the oxide layer (130) by maintaining temperature (131) of the semiconductor structure within a refinement temperature range extending from 20° C., to 800° C., and maintaining total pressure (132) in the vacuum chamber below a maximum total pressure, of 1×10⁻³ mbar.

### FIELD OF TECHNOLOGY

This disclosure concerns semiconductor technology. In particular, this disclosure concerns passivation of semiconductor structures and devices.

### BACKGROUND

In conventional semiconductor devices, semiconductor surfaces are often passivated by growing an oxide layer onto said surfaces. However, many methods for forming oxides result in oxide layers with considerable defect densities. This necessarily leads to existence of defect states at passivated semiconductor surfaces, inevitably deteriorating performance of conventional semiconductor devices. Moreover, conventional methods for forming oxides may rely on relatively high processing temperatures, which may deteriorate properties of semiconductor substrates and/or structures fabricated onto such substrates. In light of such challenges, it may be desirable to develop new solutions related to passivation of semiconductor structures and devices.

### SUMMARY

This summary is provided to introduce a selection of concepts in a simplified form that are further described below in the Detailed Description. This Summary is not intended to identify key features or essential features of the claimed subject matter, nor is it intended to be used to limit the scope of the claimed subject matter.

According to a first aspect, a method for passivating a semiconductor structure, comprising a semiconductor layer and an oxide layer on the semiconductor layer, is provided. The method comprises providing the semiconductor structure in a vacuum chamber and, while keeping the semiconductor structure in the vacuum chamber throughout a refinement period (RP) with a duration (t_{RP}) of at least 25 seconds (s), refining the oxide layer by maintaining temperature (T) of the semiconductor structure within a refinement temperature range (ΔT) extending from 20 degrees Celsius (° C.) to 800° C., and maintaining total pressure (pₜₒₜ) in the vacuum chamber below a maximum total pressure (pₜₒₜ^{max}) of 1×10⁻³ millibars (mbar).

According to a second aspect, a semiconductor structure passivated using a method in accordance with the first aspect is provided.

It is specifically to be understood that a semiconductor structure according to the second aspect may be passivated using any method according to the first aspect. Correspondingly, any semiconductor structure according to the second aspect may be passivated using a method according to the first aspect.

According to a third aspect, a vacuum processing system is provided. The vacuum processing system comprises a vacuum chamber; a pumping unit for evacuating the vacuum chamber; a pressure sensor for measuring total pressure (pₜₒₜ) in the vacuum chamber; a temperature-controlled sample holder for holding a sample in the vacuum chamber; and a control unit operatively coupled with the pumping unit, the pressure sensor, and the sample holder and configured to receive sample structure data relating to a structure of a sample to be processed by the vacuum processing system and sample position data indicative of a position of the sample to be processed. In response to receiving sample structure data indicative of a sample with a semiconductor layer and an oxide layer on the semiconductor layer and sample position data indicative of the sample being arranged in the sample holder, the control unit is configured to run a process of refining the oxide layer in accordance with a process of refining the oxide layer of a method in accordance with the first aspect by operating the pumping unit, the pressure sensor, and the sample holder.

It is specifically to be understood that the vacuum processing system according to the third aspect may be specifically configured to execute any method according to the first aspect.

### BRIEF DESCRIPTION OF THE DRAWINGS

The present disclosure will be better understood from the following Detailed Description read in light of the accompanying drawings, wherein:

FIG. 1 illustrates a method for passivating a semiconductor structure,

FIG. 2 depicts a semiconductor structure, and

FIG. 3 shows s schematic representation of a vacuum processing system.

Unless specifically stated to the contrary, any drawing of the aforementioned drawings may be not drawn to scale such that any element in said drawing may be drawn with inaccurate proportions with respect to other elements in said drawing in order to emphasize certain structural aspects of the embodiment of said drawing.

### DETAILED DESCRIPTION

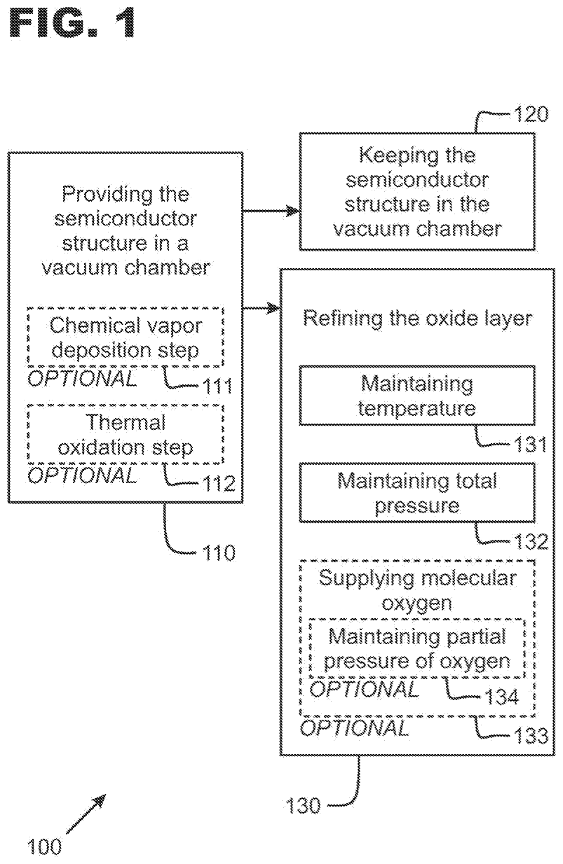

FIG. 1 depicts a method 100 for passivating a semiconductor structure, comprising a semiconductor layer and an oxide layer on the semiconductor layer, according to an embodiment.

In this specification, a “semiconductor” may refer to a material, such as silicon (Si), possessing a conductivity intermediate between the conductivity of conductive materials, such as metals, and the conductivity of insulating materials, such as many plastics and glasses. Further, a “semiconductor structure” may refer to a structure which may comprise all or only part of structural parts, layers, and/or other elements of a complete, operable semiconductor device, e.g., a diode; a photodiode; a solar cell; a photodetector; a radiation detector; an image sensor; a light-emitting diode; a laser diode; a capacitor; a transistor; or an integrated circuit, such as a microprocessor, a microcontroller, a memory chip, a programmable logic device, a radio frequency (RF) circuit, or a three-dimensional integrated circuit; or a memristor. In the case of forming only a part of such component, element, or device, the term “structure” may be considered as a structure “for”, or a building block of, such component, element, or device. A semiconductor structure may generally comprise non-semiconducting materials, such as conductors and/or insulators, in addition to semiconductor materials.

Throughout this disclosure, “passivation” may refer to a process, whereby a structure of device becomes less sensitive to its surroundings during use. Passivation may involve the formation of one or more protective outer layers, which may or may not be implemented as oxide layers. Additionally or alternatively, passivation may refer to surface passivation, i.e., a process, whereby a surface of semiconductor layer may be rendered more inert.

Herein, a “layer” may refer to a generally sheet-shaped element arranged on a surface or a body. Additionally or alternatively, a layer may refer to one of a series of super-imposed, overlaid, or stacked generally sheet-shaped elements. Generally, the extent of a layer may or may not be defined by a boundary between different materials or material compositions. However, a “semiconductor layer” may refer to a layer formed of a semiconductor material, and an “oxide layer” may refer to a layer formed of an oxide material.

In the embodiment of FIG. 1, the method 100 comprises a process of providing the semiconductor structure 110 in a vacuum chamber.

In this specification, a “process” may refer to a series of one or more steps, leading to an end result. As such, a process may be a single-step or a multi-step process. Additionally, a process may be divisible to a plurality of sub-processes, wherein individual sub-processes of such plurality of sub-processes may or may not share common steps. Herein, a “step” may refer to a measure taken in order to achieve a pre-defined result.

Throughout this disclosure, a “vacuum chamber” may refer to an enclosure configured to withstand evacuation by a vacuum pump. Additionally or alternatively, a vacuum chamber may refer to an enclosure suitable for maintaining a low-pressure environment brought about by such evacuation, i.e., a vacuum, in said enclosure.

Further, “providing” may refer to arranging available the element or item at issue. It may comprise forming, producing, or manufacturing the element or part at issue at least partly. Additionally or alternatively, providing may comprise arranging available an element or part which is ready-made or produced or manufactured beforehand. For example, a process of providing the semiconductor structure may or may not comprise one or more steps taken in order to form a semiconductor structure.

Consequently, in the embodiment, of FIG. 1, the process of providing the semiconductor structure 110 may comprise a chemical vapor deposition step 111 and/or a thermal oxidation step 112 for forming at least part of the oxide layer. Generally, a chemical vapor deposition step may enable forming a variety of different combinations of semiconductor layers and oxide layers. On the other hand, a thermal oxidation step may yield an oxide layer with a lower defect density. In other embodiments, a process of providing the semiconductor structure may or may not comprise a chemical vapor deposition step and/or a thermal oxidation step for forming at least part of an oxide layer of the providing the semiconductor structure.

The chemical vapor deposition step 111 of the embodiment of FIG. 1 may be implemented, for example, as a low pressure chemical vapor deposition (LPCVD) step or an atomic layer deposition (ALD) step. Generally, an LPCVD step may provide higher oxide layer deposition rates, whereas an ALD step may provide higher thickness uniformity for an oxide layer. In other embodiments, wherein a process of providing the semiconductor structure comprises a chemical vapor deposition step, said chemical vapor deposition step may be implemented as any suitable type of chemical vapor deposition step, for example, as an LPCVD step or an ALD step.

The thermal oxidation step 112 of the embodiment of FIG. 1 may be implemented, for example, as a dry oxidation step or as a wet oxidation step. Generally, a dry oxidation step may yield an oxide layer with a lower defect density, whereas a wet oxidation step may provide higher oxidation rates. In other embodiments, wherein a process of providing the semiconductor structure comprises a thermal oxidation step, said thermal oxidation step may be implemented as any suitable type of thermal oxidation step, for example, as a dry oxidation step or as a wet oxidation step.

In the embodiment of FIG. 1, the method 100 further comprises refining the oxide layer 130, while keeping the semiconductor structure 120 in the vacuum chamber throughout a refinement period (RP) with a duration (t_{RP}) of at least 30 s. Generally, a longer t_{RP} may increase an overall change in an oxide layer, e.g., in a degree of crystallinity of the oxide layer, attainable by a method for passivating a semiconductor structure. In other embodiments, RP may have any suitable t_{RP} of at least 25 s, or at least 30 s, or at least 40 s, or at least 1 minute (min), or at least 2 min, or at least 5 min, or at least 8 min, or at least 10 min, or at least 12 min, or at least 15 min, or at least 13 min, or at least 20 min, or at least 30 min, or at least 45 min, or at least 60 min, for example, a t_{RP} of 25 s or 40 s or a t_{RP} of 1 min, or 2 min, or 3 min, and so forth.

In the embodiment of FIG. 1, the process of refining the oxide layer 130 comprises maintaining temperature (T) 131 of the semiconductor structure throughout the RP within a refinement temperature range (ΔT), extending from 20° C. to 800° C. In the embodiment of FIG. 1, T may be maintained, for example, at approximately 350° C. Generally, a higher Tₛ may steepen a rate of change in an oxide layer, e.g., its degree of crystallinity, attainable by a method for passivating a semiconductor structure. On the other hand, a lower Tₛ may enable utilising a method for passivating a semiconductor structure in situations, wherein tighter thermal budgets must be held onto. In other embodiments, a process of refining the oxide layer may comprise maintaining T of a semiconductor structure throughout a RP within any suitable ΔT, for example a ΔTₛ extending from 50° C. to 750° C., or from 80° C. to 700° C., or from 100° C. to 650° C., or from 130° C. to 600° C., or from 160° C. to 550° C., or from 180° C. to 520° C., or from 200° C. to 500° C., or from 220° C. to 480° C., or from 240° C. to 460° C., or from 260° C. to 440° C., or from 280° C. to 420° C., or from 300° C. to 400° C., or from 320° C. to 380° C.

Throughout this specification, “degree of crystallinity” may refer to a fraction of crystalline phase(s) in a material. Herein, the degree of crystallinity of an oxide layer may refer to a value determinable based on X-ray diffraction measurements.

In the embodiment of FIG. 1, the process of refining the oxide layer 130 comprises maintaining total pressure (pₜₒₜ) 132 in the vacuum chamber below a maximum total pressure (pₜₒₜ^{max}) of 1×10⁻³ mbar throughout the RP. Generally, a lower pₜₒₜ^{max} may steepen a rate of change in an oxide layer, e.g., its degree of crystallinity, attainable by a method for passivating a semiconductor structure. On the other hand, a higher pₜₒₜ^{max} may loosen technical requirements for maintaining pₜₒₜ below pₜₒₜ^{max} and/or reduce resource consumption during use of a method for passivating a semiconductor structure. In other embodiments, a process of refining the oxide layer may comprise maintaining pₜₒₜ in a vacuum chamber below any suitable pₜₒₜ^{max} of at most 1×10⁻³ mbar, for example, maintaining pₜₒₜ below a pₜₒₜ^{max} of 1×10⁻³ mbar, or 5×10⁻⁴ mbar, or 1×10⁻⁴ mbar, or 5×10⁻⁵ mbar, or 1×10⁻⁵ mbar, or 5×10⁻⁶ mbar, or 2×10⁻⁶ mbar.

Generally, refining the oxide layer of a semiconductor structure by maintaining T of the semiconductor structure within ΔT, extending from 20° C., 800° C., and maintaining pₜₒₜ in a vacuum chamber below pₜₒₜ^{max} of 1×10⁻³ mbar, while keeping the semiconductor structure in the vacuum chamber throughout a RP with a t_{RP} of at least 25 s, may enable passivating the semiconductor structure. Without necessarily limiting the present disclosure to any specific underlying physical mechanism(s), such passivation may result from lowered density of defect states at an interface between a semiconductor layer and an oxide layer, brought about by an increase in the degree of crystallinity of the oxide layer. Again, without necessarily limiting the present disclosure to any specific underlying physical mechanism(s), such passivation may additionally or alternatively result from re-arrangement of hydrogen atoms inside the semiconductor layer due to diffusion.

In the embodiment of FIG. 1, the process of refining the oxide layer 130 may comprise supplying molecular oxygen (O₂) 133 into the vacuum chamber 310 throughout the RP. Generally, supplying molecular oxygen into a vacuum chamber may facilitate refining the oxide layer of a semiconductor structure, especially if the oxide layer is sub-stoichiometric, i.e., oxygen-deficient. In other embodiments, a process of refining the oxide layer may or may not comprise supplying O₂ into a vacuum chamber. In other embodiments, a process of refining the oxide layer of a semiconductor structure may or may not comprise supplying molecular oxygen into a vacuum chamber.

In the embodiment of FIG. 1, the process of supplying molecular oxygen 133 may comprise maintaining partial pressure of oxygen (pₒ_{₂}) 134 in the vacuum chamber above a minimum partial pressure of oxygen (pₒ_{₂}^{min}) of 4×10⁻⁹ mbar throughout the RP. Generally, a higher pₒ_{₂} may steepen a rate of change in an oxide layer, e.g., its degree of crystallinity, attainable by a method for passivating a semiconductor structure, especially if the oxide layer is sub-stoichiometric. In other embodiments, wherein a process of refining the oxide layer of a semiconductor structure comprises supplying molecular oxygen into a vacuum chamber, the process of supplying molecular oxygen way or may not comprise maintaining pₒ_{₂} above any suitable pₒ_{₂}^{min}, for example, a pₒ_{₂}^{min} of 4×10⁻⁹ mbar, or 9×10⁻⁹ mbar, or 4×10⁻³ mbar, or 9×10⁻⁸ mbar, or 4×10⁻⁷ mbar, or 9×10⁻⁷ mbar throughout a RP.

Generally, a process of refining the oxide layer may comprise supplying one or more gases other than O₂ into a vacuum chamber during or throughout a RP, in addition or as an alternative to supplying O₂. For example, in some embodiments, a process of refining the oxide layer may comprise supplying one or more of molecular hydrogen (H₂), hydrogen peroxide (H₂O₂), ammonia (NH₅), molecular nitrogen (N₂), nitrogen dioxide (NO₂), ethanol (C₂H₅OH), and noble gas(es), e.g., helium (He) or Argon (Ar). In embodiments, wherein a process of refining the oxide layer comprises supplying a gas other than O₂ into a vacuum chamber during or throughout a RP, the process of refining the oxide layer may or may not comprise maintaining a partial pressure of the gas above a minimum partial pressure of the gas with a value corresponding to some value of pₒ_{₂}^{min} disclosed in this specification.

In an embodiment, a method for passivating a semiconductor structure comprises processes corresponding to the processes 110, 120, 130, 131, 132, 133, and 134 of the method 100 of the embodiment of FIG. 1. In other embodiments, a method for passivating a semiconductor structure may comprise processes corresponding to the compulsory processes 110, 120, 130, 131, and 132 of the method 100 of the embodiment of FIG. 1.

Generally, steps of a method for passivating a semiconductor structure implementing processes corresponding to any of the processes 110, 120, 130, 131, 132, 133, and 134 of the method 100 of the embodiment of FIG. 1 may be executed in any suitable order. In general, a method for passivating s semiconductor structure may comprise any number of additional processes or steps that are not disclosed herein in connection to the method 100 of the embodiment of FIG. 1.

Above, mainly process and parameter issues of methods for passivating semiconductor structures are discussed. In the following, more emphasis will lie on structural features of semiconductor structures before and after being passivated using a method in accordance with any method disclosed within this specification. What is said above about the ways of implementation, definitions, details, and advantages related to the process and parameter issues apply, mutatis mutandis, to the semiconductor structures discussed below. The same applies vice versa.

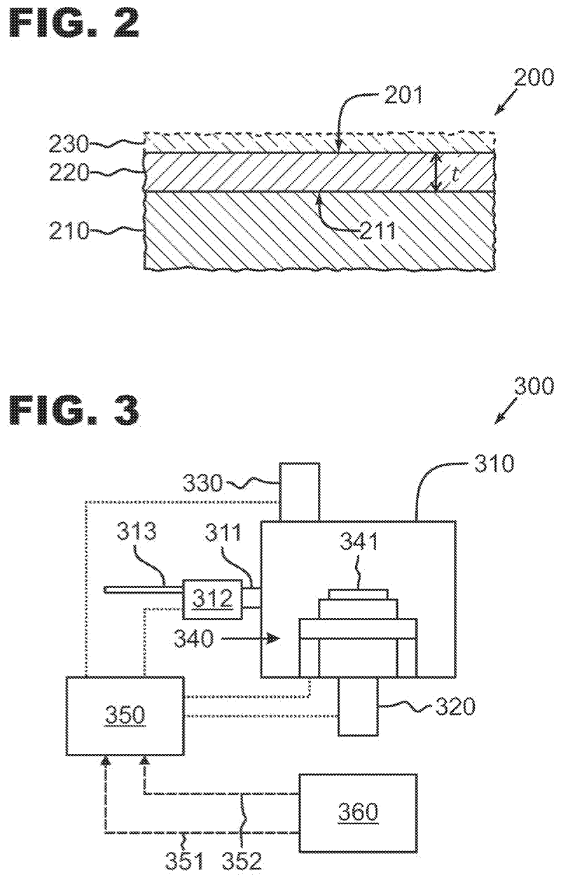

FIG. 2 depicts a semiconductor structure 200 according to an embodiment.

The semiconductor structure 200 of the embodiment of FIG. 2 comprises a semiconductor layer 210 and an oxide layer 220 on the semiconductor layer 210.

In the embodiment of FIG. 2, the semiconductor structure 200 may comprise a capping layer 230, covering the oxide layer 220 each that the oxide layer 220 is arranged at a distance from a periphery of the semiconductor structure 200. Alternatively, the oxide layer 220 may extend along a periphery 201 of the semiconductor structure 200. Generally, an oxide layer extending along a periphery of a semiconductor structure may steepen a rate of change in an oxide layer, e.g., its degree of crystallinity, attainable by a method for passivating a semiconductor structure, especially if, in the method, a process of refining the oxide layer comprises supplying molecular oxygen into a vacuum chamber. In other embodiments, an oxide layer may or may not extend along a periphery of a semiconductor structure.

Throughout this specification, a “capping layer” may refer to any layer arranged on an oxide layer of a semiconductor structure such that the oxide layer is arranged at a distance from a periphery of the semiconductor structure.

Further, a “periphery” of an object may refer to outermost boundaries of the object. In practice, such outermost boundaries may be considered to extend a nanoscopic distance, for example, at most 20 nanometers, nm, or at most 10 nm, or at most 5 nm, or at most 2 nm, towards a center of an object, from its outermost atoms.

Prior to being subjected to a process of refining the oxide layer 220, the oxide layer 220 has a first degree of crystallinity (w₁^{c}). In the embodiment of FIG. 2, w₁^{c} may be, for example, approximately 2 percent by mass (m %). Generally, an oxide layer with a lower first degree of crystallinity way exhibit a greater relative increase in its degree of crystallinity by being subjected to a process of refining the oxide layer. Additionally or alternatively, sore oxide materials nay be harder to produce with higher degrees of crystallinity. In other embodiments, an oxide layer may have any suitable w₁^{c} prior to being subjected to a process of refining the oxide layer, for example, a w₁^{co}f at most 50 m %, or at most 40 m %, or at most 30 m %, or at most 20 m %, or at most 15 m %, or at most 10 m %, or at most 5 m %, or at most 2 m %, or at most 1 m %.

After being subjected to a process of refining the oxide layer 220, the oxide layer 220 has a second degree of crystallinity (w₂^{c}), which nay be greater than w₁^{c}. In the embodiment of FIG. 2, w₂^{c} may be, for example, approximately 10 m %. In other embodiments, an oxide layer may have any suitable w₂^{c} after being subjected to a process of refining the oxide layer, for example, a w₂^{c} of at least 10 m %, or at least 15 m %, or at least 20 m %, or at least 25 m %, or at least 35 m %, or at least 45 m %, or at least 55 m %.

The oxide layer 220 of the embodiment has a thickness (t), measured following a process of refining the oxide layer and perpendicular to an interface between the semiconductor layer 210 and the oxide layer 220. In the embodiment of FIG. 2, t may be, for example, approximately 2 nm. In other embodiments, an oxide layer may have any suitable t, measured following a process of refining the oxide layer and perpendicular to an interface between a semiconductor layer and the oxide layer, for example, a t of at least 1 nm, or at least 2 nm, or at least 5 nm, or at least 8 nm, or at least 10 nm, or at least 12 nm, or at least 15 nm, ox at least 20 nm, or at least 25 nm, ox at least 30 nm, or at least 40 nm, or at least 50 nm, or at least 60 nm, or at least 75 nm, or at least 100 nm.

The semiconductor layer 210 of the embodiment of FIG. 2 may have a crystalline, for example, monocrystalline, structure. Generally, a semiconductor layer with a crystalline, e.g., polycrystalline ox monocrystalline, structure may enable formation of epitaxial oxide on the semiconductor layer, which may result in lower defect density between a semiconductor layer and an oxide layer after a process of refining the oxide layer. In other embodiments, a semiconductor layer may have any suitable type of microstructure, for example, a crystalline, e.g., a polycrystalline or monocrystalline, structure; a semicrystalline structure; or an amorphous structure. Herein, “crystalline” structure of a material may refer to constituents, such as atomic nuclei, of said material forming at least one ordered, two-dimensional or three-dimensional crystal, lattice.

In the embodiment of FIG. 2, the semiconductor layer 210 has a first main constituent element, and the oxide layer 220 is implemented as a layer of an oxide of the first constituent element. Such correspondence between the atomic constituents of a semiconductor layer and an oxide layer may generally facilitate refining the oxide layer, especially if the semiconductor layer has a crystalline structure. In other embodiments, an oxide layer may or may not be implemented as a layer of an oxide of a first main constituent element of a semiconductor layer.

Herein, a “main constituent element” of a layer may refer to a chemical element of an atomic nucleus of a repeating structural motif or a lattice of material in the layer.

The first main constituent element of the embodiment of FIG. 2 may be Si. In other embodiments, wherein an oxide layer is implemented as an oxide of a first main constituent element of a semiconductor layer, said first main constituent element may be any suitable element, for example, Si or germanium (Ge), or gallium (Ga), without necessarily limiting the scope of suitable elements to these examples.

The semiconductor layer 210 of the embodiment of FIG. 2 may have a single main constituent element. As such, the semiconductor layer 210 may have a monatomic structure. In other embodiments, a semiconductor layer may or may not have a monoatomic structure. In some embodiments, a semiconductor layer may have a polyatomic, e.g., diatomic or triatomic, structure.

The semiconductor layer 210 of the embodiment of FIG. 2 may be implemented specifically as a Si layer. In other embodiments, a semiconductor layer may or may not be implemented as a Si layer. In other embodiments, a semiconductor layer may be implemented as any suitable type of semiconductor layer. In some embodiments, a semiconductor layer may be implemented, for example, as a group IV elemental semiconductor layer, e.g., a Si layer or a Ge layer; or as a group IV compound semiconductor layer, e.g., a silicon carbide (SiC) layer; or as a group V elemental semiconductor layer, e.g., a tellurium (Te) layer; or as a IV-VI compound semiconductor layer, e.g., lead telluride (PbTe) layer or a tin(IV) sulfide (SnS₂) layer; or as a III-V compound semiconductor layer, e.g., a gallium nitride (GaN) layer or an indium phosphide (InP) layer; or as a II-VI compound semiconductor layer, e.g., a cadmium selenide (CdSe) layer; or as a I-VII compound semiconductor layer, e.g., a copper sulfide (CuS) layer; or as an oxide semiconductor layer, e.g., titanium dioxide (TiO₂) layer, or a copper(I) oxide (Cu₂O) layer, or a semiconducting complex oxide layer; or as an alloy semiconductor layer, e.g., a silicon-germanium (Si_{1-z}Geₓ) layer, or an indium gallium arsenide (InₓGa₁₋ₓAs) layer, or a gallium indium arsenide antimonide phosphide (Ga₁₋ₓInₓAsₓSbₓP_{1-y-z}); or as a hybrid organic-inorganic perovskite-structured semiconductor layer, e.g. methylammonium lead halide (MALH) layer; or as a two-dimensional semi conductor layer, e.g., a graphene layer or a transition metal dichalcogenide (TMDC) layer.

The oxide layer 220 of the embodiment of FIG. 2 may be implemented specifically as a silicon oxide (SiO₂, 0<x≤2) layer. In other embodiments, a semiconductor layer may or may not be implemented as such SiOₓ layer. In other embodiments, an oxide layer may be implemented as any suitable type of oxide layer. In some embodiments, an oxide layer may be implemented, for example, as an electrically insulating oxide layer, e.g., an aluminum oxide (Al₂O₂) layer; or as a semiconducting oxide layer, e.g., a TiO₂ layer, or a Cu₂O layer, or a semiconducting complex oxide layer; or as an electrically conducting oxide layer, e.g., an indium tin oxide (ITO) layer or an aluminum-doped zinc oxide (AZO) layer.

In the embodiment of FIG. 2, the semiconductor structure 200 may be subjected to at least one of a wafer slicing step, a wafer lapping step, an etching step, a polishing step, a cleaning step, a scribing step, and a dicing step prior to a process of providing the semiconductor structure in a vacuum chamber. As such, the semiconductor layer 210 may comprise a surface 211 that is damaged by at least one of the following: a wafer slicing step, a wafer lapping step, an etching step, a polishing step, a cleaning step, a scribing step, and a dicing step. Consequently, the surface 211 may be passivated after having been damaged by at least one of the aforementioned steps by a method for passivating a semiconductor structure in accordance with any method disclosed in this specification. In other embodiments, a surface of a semiconductor layer may or may not be passivated by a method for passivating a semiconductor structure in accordance with any method disclosed in this specification after having been damaged by at least one of the following: a wafer slicing step, a wafer lapping step, an etching step, a polishing step, a cleaning step, a scribing step, and a dicing step.

In the following, a number of examples are detailed.

In a first example, a silicon dioxide (SiO₂) layer was grown by atomic layer deposition onto an unpatterned 4-inch Si sample wafer and a corresponding reference wafer.

The sample wafer was then placed into the cylindrical stainless-steel vacuum chamber of an ultra-high vacuum (UHV) system. In the system, the vacuum chamber was connected to a turbomolecular pump with a rotary backing pump, and an all-metal gas regulating valve was connected to the vacuum chamber for adjusting the partial pressure of oxygen (pₒ_{₂}) in the vacuum chamber during operation of the UHV system. The system was also equipped with a cold cathode pressure gauge suitable for measuring pressures above approximately 1×10⁻⁹ mbar in oxygen-containing environments.

Inside the vacuum chamber, the sample wafer was mounted onto a cradle formed of an austenitic nickel-chromium-based superalloy material without the use of plates, bolts, or clams to fix the wafer onto the cradle. When mounted on the cradle, the temperature of the wafer could be controlled by a heating system, comprising a heating element as well as a combined temperature controller-power supply device connected to a type K thermocouple.

While the sample wafer was kept in the vacuum chamber, the total pressure (pₜₒₜ) in the vacuum chamber was maintained below a maximum total pressure (pₜₒₜ^{max}) of approximately 5×10⁻⁶ mbar, the temperature of the wafer was maintained at 350° C., and the partial pressure of oxygen (pₒ_{₂}) in the vacuum chamber was maintained at 1×10⁻⁶ mbar throughout a refinement period (RP) with a duration (t_{RP}) of 200 s.

During the refinement period, reflection high-energy electron diffraction (RHEED) measurements were conducted to study the morphology of the SiO₂ layer. Results of the RHEED measurements indicated that, the degree of crystallinity of the SiO₂ layer increased during the treatment of the sample wafer in the vacuum chamber.

Following the treatment of the sample wafer in the vacuum chamber, carrier lifetime measurements were conducted on both the sample wafer and the reference wafer using a Semilab PV-2000A lifetime scanner tool. The results of the carrier lifetime measurements indicated that the treatment of the sample wafer in the vacuum chamber resulted in an increase in average carrier lifetime from 2.12 milliseconds (ms) to 2.90 ms.

In a second example, a Si photodiode sample with alumina-coated black silicon (b-Si) surface featuring and a size of 6 mm×6 mm was diced from a Si wafer after completion of wafer-scale device processing. The dicing step introduced scratches to the sidewalls of the photodiode sample and exposed the sidewalls to the ambient such that native oxide formed to cover the sidewalls.

The photodiode sample was then placed into a temperature-controlled sample holder of a vacuum chamber of a UHV system. While the photodiode sample wafer was kept in the vacuum chamber, the total pressure (pₜₒₜ) in the vacuum chamber was maintained below a maximum total pressure (pₜₒₜ^{max}) of 2×10⁻⁴ mbar, the temperature of the wafer was maintained at 400° C., and the partial pressure of oxygen (pₒ_{₂}) in the vacuum chamber was maintained at 1×10⁻⁴ mbar throughout a refinement period (RP) with a duration (t_{RP}) of 30 min.

Leakage current measurements were carried out for the photodiode sample before and after the vacuum treatment using an LCR precision meter at a controlled temperature without illumination. According to the results of the leakage current measurements, the vacuum treatment resulted in decreased leakage currents for the photodiode sample. Such results may be indicative of the vacuum treatment decreasing the density of defect-induced gap levels in the proximity of the sidewalls. Such effect may be caused by a reformation of the structure of the oxide layers on the sidewalls.

In a third example, a photodiode sample identical to the photodiode sample of the second sample was prepared and placed into a temperature-controlled sample holder of a vacuum chamber of a UHV system. While the photodiode sample wafer was kept in the vacuum chamber, the total pressure (pₜₒₜ) in the vacuum chamber was maintained below a maximum total pressure (pₜₒₜ^{max}) of 1×10⁻⁵ mbar, the temperature of the wafer was maintained at 200° C., and the partial pressure of oxygen (pₒ_{₂}) in the vacuum chamber was maintained at 5×10⁻⁶ mbar throughout a refinement period (RP) with a duration (t_{RP}) of 30 min.

Similarly to the second example, leakage current measurements were carried cut for the photodiode sample before and after the vacuum treatment. According to the results of the leakage current measurements, the vacuum treatment resulted in decreased leakage currents for the photodiode sample. Such results may be indicative of the vacuum treatment decreasing the density of defect-induced gap levels in the proximity of the sidewalls. Such effect may be caused by a reformation of the structure of the oxide layers on the sidewalls.

It is to be understood that the embodiments of the first and second aspects described above may be used in combination with each other. Several of the embodiments may be combined together to form a further embodiment of the first aspect or the second aspect.

Above, mainly process and parameter issues of methods for passivating semiconductor structures and structural features of semiconductor structures before and after being passivated using such methods are discussed. In the following, more emphasis will lie on features of vacuum processing systems configured to realize methods in accordance with any method disclosed within this specification. What is said above about the ways of implementation, definitions, details, and advantages related to the method and semiconductor structure aspects apply, mutatis mutandis, to the vacuum processing systems discussed below. The same applies vice versa.

FIG. 3 depicts a schematic representation of a vacuum processing system 300 according to an embodiment.

In the embodiment of FIG. 3, the vacuum processing system 300 comprises a vacuum chamber 310.

In the embodiment of FIG. 3, the vacuum processing system 300 further comprises a pumping unit 320 for evacuating the vacuum chamber 310.

Herein, a “pumping unit” may refer to apparatus e.g., vacuum pumps and electronics, as well as interconnect ion elements, e.g., valves, sealing elements, and gas lines, necessary or beneficial for evacuating a vacuum chamber.

In the embodiment of FIG. 3, the vacuum processing system 300 further comprises a pressure sensor (330) for measuring total pressure (pₜₒₜ) in the vacuum chamber 310.

Herein, a “pressure sensor” may refer to any device for measuring (static) pressure of gases in a vacuum chamber. Generally, selection of a suitable type of commercially available pressure sensor for any given application may be considered standard practice for the skilled person. For example, in oxygen-containing environments, a cold cathode pressure gauge may foe commonly used to measure pressures above approximately 1×10⁻⁹ mbar.

In the embodiment of FIG. 3, the vacuum processing system 300 further comprises a ten-perature-controlled sample holder 340 for holding a sample 341 in the vacuum chamber 310.

Herein, a “temperature-controlled sample holder” may refer to a part of a vacuum processing system specifically configured for holding as well as heating, and, optionally, cooling a sample in a vacuum chamber, when the vacuum processing system is used. Such sample holder may comprise, for example, electrical connections for conducting electrical measurements on a sample inside a vacuum chamber; and/or an integrated quartz balance for measuring a mass of a sample; and/or sample heating element(s), which may be based, for example, on resistive, electron bombardment, and/or direct heating of a sample; and/or sample cooling element(s), which may utilize, for example, cryogenic cooling. Generally, selection of a suitable type of commercially available sample holder for any given application may be considered standard practice for the skilled person.

In the embodiment of FIG. 3, the vacuum processing system 300 further comprises a control unit 350 operatively coupled with the pumping unit 320, the pressure sensor 330, and the sample holder 340. In FIG. 3, such operative couplings are schematically displayed by dotted lines.

In this specification, a “control unit” may refer to a device, e.g., an electronic device, having at least one specified function related to determining and/or influencing an operational condition, status, or parameter related to another device, unit, or element. A control unit, may or may not form a part of a multifunctional control system.

Further, a control unit being “operatively coupled” with a device, unit, or element may refer to the control unit having at least one specified function related to determining and/or influencing an operational condition, status, or parameter related to said device, unit, or element.

The control unit 350 of the embodiment of FIG. 3 is configured to receive sample structure data 351 relating to a structure of a sample (341) to be processed by the vacuum processing system (300) and sample position data 332.

A control unit being “configured to” perform a process may refer to capability of and suitability of said control unit for such process. This may be achieved in various ways. For example, a control unit may comprise at least one processor and at least one memory coupled to the at least one processor, the memory storing program code instructions which, when executed on said at least one processor, cause the processor to perform the process(es) at issue.

Additionally or alternatively, any functionally described features of a control unit may be performed, at least in part, by one or more hardware logic components. For example, and without limitation, illustrative types of suitable hardware logic components include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. A control unit may generally be operated in accordance with any appropriate principles and by means of any appropriate circuitry and/or signals known in the art.

Herein, “sample structure data” may refer to any data relating to a structure of a sample to be processed by a vacuum processing system. In some embodiments, sample structure data may comprise, for example, a partial or complete fabrication recipe of a sample. In some embodiments, sample structure data may comprise recipe data used exclusively for a particular sample type.

Throughout this specification, “sample position data” may refer to any data indicative of a position of the sample to be processed by a vacuum processing system. In some embodiments, sample structure data may comprise, for example, a start signal, indicating that processing of a sample may be initiated. Such start signal may be sent, for example, in response to automatically sensing that a sample is arranged into a sample holder or in response to user input.

The control unit 350 of the embodiment of FIG. 3 is further configured to run a process of refining the oxide layer in accordance with a process of refining the oxide layer of any method for passivating a semiconductor structure disclosed in this specification in response to receiving sample structure data 351 indicative of a sample 341 with a semiconductor layer and an oxide layer on the semiconductor layer and sample position data 352 indicative of the sample being arranged in the sample holder 340. The control unit 350 runs the process by operating the pumping unit 320, the pressure sensor 330, and the sample holder 340. In other embodiments, a control unit may be configured to run such process of refining the oxide layer in response to receiving sample structure data indicative of a sample with a semiconductor layer and an oxide layer on the semiconductor layer and, optionally, indicative also of one or more structural features of semiconductor structures disclosed within this specification and sample position data indicative of the sample being arranged in a sample holder.

The vacuum chamber 310 of the embodiment of FIG. 3 comprises a gas inlet 311 with a pressure regulator 312 operatively coupled with the control unit 350. In other embodiments, a vacuum chamber may or may not comprise such gas inlet with such pressure regulator.

Herein, a “pressure regulator” of a gas inlet may refer to a control valve suitable for or configured to set, e.g., reduce, a pressure of gas supplied via the gas inlet to a desired value or within a desired pressure range.

In the embodiment of FIG. 3, the vacuum processing system 300 comprises an oxygen line (313) for supplying O₂ into the vacuum chamber 310 via the gas inlet 311. In other embodiments, a vacuum processing system may or may not comprise such oxygen line.

The process of refining the oxide layer of the embodiment of FIG. 3 may be in accordance with any process of refining the oxide layer disclosed in this specification, comprising supplying molecular oxygen into a vacuum chamber. In case the process of refining the oxide layer comprises supplying molecular oxygen into a vacuum chamber, the control unit (350) may be configured to run the process of refining the oxide layer by operating the pumping unit 320, the pressure sensor 330, the sample holder 340, and the pressure regulator 312. In other embodiments, a process of refining the oxide layer may or may not be in accordance with a process of refining the oxide layer disclosed in this specification comprising supplying molecular oxygen into a vacuum chamber. In embodiments, wherein a process of refining the oxide layer comprises supplying, molecular oxygen into a vacuum chamber, a control unit may be configured to run the process of refining the oxide layer by operating a pumping unit, a pressure sensor, a sample holder, and a pressure regulator.

Generally, a process of refining the oxide layer run by a control unit may comprise supplying one or more gases other than O₂ into a vacuum chamber during or throughout a RP, in addition or as an alternative to supplying O₂. For example in some embodiments such process of refining the oxide layer nay comprise supplying one or more of molecular hydrogen (H₂), hydrogen peroxide (H₂O₂), ammonia (NH₃), molecular nitrogen (N₂), nitrogen dioxide (NO₂), ethanol (C₂H₅OH), and noble gas(es), e.g., helium (He) or Argon (Ar). In embodiments, wherein a process of refining the oxide layer run by a control unit of a vacuum processing system comprises supplying a gas other than O₂ into a vacuum chamber during or throughout a RP, the vacuum processing system may comprise any element(s) required for supplying the gas, for example, a gas inlet with a pressure regulator and a gas line for supplying the gas into the vacuum chamber via the gas inlet. In said embodiments, the control unit may be configured to run the process of refining the oxide layer by operating a pumping unit, a pressure sensor, a sample holder, and the pressure regulator.

In the embodiment of FIG. 3, the vacuum processing system 300 further comprises a user interface unit 360 for sending sample structure data 351 and sample position data 352 to the control unit 350 in response to user input. In other embodiments, a vacuum processing system may or may not comprise a user interface unit for sending sample structure data and/or sample position data to a control unit in response to user input. A vacuum processing system may generally comprise any known means, devices, and/or procedures for providing a control unit with sample structure data and/or sample position data. For example, in some embodiments, sample position data may be automatically sent to a control unit in response to detecting a sample in a sample holder or a sample being set in a sample holder. Additionally or alternatively, in some embodiments, sample structure data may be sent to a control unit in response to an automated analysis procedure conducted for a sample arranged in a sample holder.

Herein, a “user interface unit” may refer to a unit configured to provide a user interface for operating a vacuum processing system. Generally, a user interface unit may comprise any elements and/or devices necessary or beneficial for providing such user interface. A user interface unit may comprise, for example, an input device, e.g., a button, a switch, a pedal, a keyboard, a mouse, a track-ball, or a lever, and/or a display device, which may generally be based on any known display technologies. In some embodiments, a user interface unit may comprise a touchscreen, usable as both an input device and a display device. In some embodiments, user interface unit may be implemented as software, for example, as a computer program.

It is to be understood that the embodiments of the third aspect described above may be used in combination with each other. Several of the embodiments may be combined together to form a further embodiment.

It is obvious to a person skilled in the art that with the advancement of technology, the basic idea of the invention may be implemented in various ways. The invention and its embodiments are thus not limited to the examples described above, instead they may vary within the scope of the claims.

It will be understood that any benefits and advantages described within this specification may relate to one embodiment or may relate to several embodiments. The embodiments are not limited to those that solve any or all of the stated problems or those that have any or all of the stated benefits and advantages.

The term “comprising” is used in this specification to mean including the feature(s) or act(s) followed thereafter, without excluding the presence of one or more additional features or acts. It will further be understood that reference to ‘an’ item refers to one or more of those items.

REFERENCE SIGNS

| RP | refinement period |
|---|---|
| t_{RP} | duration of the refinement period |
| T | temperature of the semiconductor structure |
| ΔT | refinement temperature range |
| pₜₒₜ | total pressure in the vacuum chamber |
| pₜₒₜ^{max} | maximum total pressure |
| p_{O}_{₂} | partial pressure of oxygen in the vacuum chamber |
| t | thickness of the oxide layer |
| p_{O}_{₂}^{min} | minimum partial pressure of oxygen |
| w₁^{c} | first degree of crystallinity |
| w₂^{c} | second degree of crystallinity |
| 100 | method |
| 110 | providing the semiconductor structure |
| 111 | chemical vapor deposition step |
| 112 | thermal oxidation step |
| 120 | keeping the semiconductor structure in the vacuum chamber |
| 130 | refining the oxide layer |
| 131 | maintaining temperature |
| 132 | maintaining total pressure |
| 133 | supplying molecular oxygen |
| 134 | maintaining partial pressure of oxygen |
| 200 | semiconductor structure |
| 201 | periphery |
| 210 | semiconductor layer |
| 211 | surface |
| 220 | oxide layer |
| 230 | capping layer |
| 300 | vacuum processing system |
| 310 | vacuum chamber |
| 311 | gas inlet |
| 312 | pressure regulator |
| 313 | oxygen line |
| 320 | pumping unit |
| 330 | pressure sensor |
| 340 | sample holder |
| 341 | sample |
| 350 | control unit |
| 351 | sample structure data |
| 352 | sample position data |
| 360 | user interface unit |

1. A method for passivating a semiconductor structure including a semiconductor layer and an oxide layer on the semiconductor layer, the method comprising:
providing the semiconductor structure in a vacuum chamber; and
while keeping the semiconductor structure in the vacuum chamber throughout a refinement period, RP, with a duration, t_{RP}, of at least 25 seconds (s),
refining the oxide layer by maintaining temperature (T) of the semiconductor structure within a refinement temperature range, ΔT, extending from 20 degrees Celsius (° C.) to 800° C.; and
maintaining total pressure, pₜₒₜ, in the vacuum chamber below a maximum total pressure, (pₜₒₜ^{max}), of 1×10⁻³ millibars (mbar).

2. The method according to claim 1, wherein the duration, t_{RP}, of the refinement period, RP, is at least one of
at least 30 s,
at least 40 s,
at least 1 minute (min),
at least 2 min,
at least 5 min,
at least 8 min,
at least 10 min,
at least 12 min,
at least 15 min,
at least 18 min,
at least 20 min,
at least 30 min,
at least 45 min, and
at least 60 min.

3. The method according to claim 1, wherein the refinement temperature range, ΔT, extends from at least one of
50° C. to 750° C.,
80° C. to 700° C.,
100° C. to 650° C.,
130° C. to 600° C., 160° C. to 550° C.,
180° C. to 520° C.,
200° C. to 500° C.,
220° C. to 480° C.,
240° C. to 460° C.,
260° C. to 440° C.,
280° C. to 420° C.,
300° C. to 400° C., and
320° C. to 380° C.

4. The method according to claim 1, wherein the maximum total pressure, (pₜₒₜ^{max}), is at least one of
5×10⁻⁴ mbar,
1×10⁻⁴ mbar,
5×10⁻⁵ mbar,
1×10⁻⁵ mbar,
5×10⁻⁶ mbar, and
2×10⁻⁶ mbar.

5. The method according to claim 1, wherein refining the oxide layer comprises supplying molecular oxygen, O₂, into the vacuum chamber.

6. The method according to claim 5, wherein supplying molecular oxygen comprises maintaining partial pressure of oxygen, pₒ_{₂}, in the vacuum chamber above a minimum partial pressure of oxygen, pₒ_{₂}^{min}, of at least one of 4×10⁻⁹ mbar, 9×10⁻⁹ mbar, 4×10⁻⁸ mbar, 9×10⁻⁸ mbar, 4×10⁻⁷ mbar, and 9×10⁻⁷ mbar throughout the refinement period, RP.

7. The method according to claim 1, wherein providing the semiconductor structure comprises performing a chemical vapor deposition that comprises at least one of
performing a low pressure chemical vapor deposition,
performing an atomic layer deposition, and
performing a thermal oxidation that comprises at least one of performing a dry oxidation or performing a wet oxidation, for forming at least part of the oxide layer.

8. The method according to claim 1, wherein the oxide layer extends along a periphery of the semiconductor structure.

9. The method according to claim 1, wherein, prior to the process of refining the oxide layer, the oxide layer has a first degree of crystallinity, w₁^{c}, of at least one of
at most 50 percent by mass (m %),
at most 40 m %,
at most 30 m %,
at most 20 m %,
at most 15 m %,
at most 10 m %,
at most 5 m %,
at most 2 m %, and
at most 1 m %.

10. The method according to claim 1, wherein the semiconductor layer has a crystalline structure.

11. The method according to claim 1, wherein the semiconductor layer has a first main constituent element, and the oxide layer is implemented as a layer of an oxide of the first main constituent element.

12. The method according to claim 11, wherein the first main constituent element is silicon, Si.

13. The method according to claim 1, whereby a surface of the semiconductor layer is passivated after having been damaged by at least one of the following:
a wafer slicing,
a wafer lapping,
an etching,
a polishing,
a cleaning,
a scribing, and
a dicing.

14. The method according to claim 1, wherein the semiconductor structure forms an operable semiconductor device that comprises at least one of
a diode,
a photodiode,
a solar,
a photodetector,
a radiation detector,
an image sensor,
a light-emitting diode,
a laser diode; a capacitor,
a transistor, and
an integrated circuit that comprises at least one of
a microprocessor,
a microcontroller,
a memory chip,
a programmable logic device,
a radio frequency (RF) circuit,
a three-dimensional integrated circuit, and
a memristor.

15. An apparatus comprising:
a semiconductor structure comprising,
a semiconductor layer; and
an oxide layer positioned on the semiconductor layer, wherein the semiconductor structure is to be passivated based on while keeping the semiconductor structure in a vacuum chamber throughout a refinement period, RP, with a duration, t_{RP}, of at least 25 seconds (s),
the oxide layer is to be refined by maintaining temperature (T) of the semiconductor structure within a refinement temperature range, ΔT, extending from 20 degrees Celsius (° C.) to 800° C. and by maintaining a total pressure, pₜₒₜ, in the vacuum chamber below a maximum total pressure, (pₜₒₜ^{max}), of 1×10⁻³ millibars (mbar).

16. A vacuum processing system comprising:
a vacuum chamber;
a pumping unit for evacuating the vacuum chamber;
a pressure sensor for measuring total pressure, pₜₒₜ, in the vacuum chamber;
a temperature-controlled sample holder for holding a sample in the vacuum chamber; and
a control unit operatively coupled with the pumping unit, the pressure sensor, and the temperature-controlled sample holder and configured to receive sample structure data relating to a structure of the sample to be processed by the vacuum processing system and sample position data indicative of a position of the sample to be processed;
wherein, in response to receiving the sample structure data indicative of the sample with a semiconductor layer and an oxide layer on the semiconductor layer and the sample position data indicative of the sample being arranged in the temperature-controlled sample holder, the control unit is configured to run a process of refining the oxide layer by maintaining temperature (T) of the sample within a refinement temperature range, ΔT, extending from 20 degrees Celsius (° C.) to 800° C. and maintaining total pressure, pₜₒₜ, in the vacuum chamber below a maximum total pressure, (pₜₒₜ^{max}), of 1×10⁻³ millibars (mbar) based on operation of the pumping unit, the pressure sensor, and the sample holder.

17. The vacuum processing system according to claim 16, wherein the vacuum chamber comprises a gas inlet with a pressure regulator operatively coupled with the control unit, the vacuum processing system comprises an oxygen line for supplying molecular oxygen, O₂, into the vacuum chamber via the gas inlet, and the control unit is configured to run the process of refining the oxide layer by operating the pumping unit, the pressure sensor, the temperature-controlled sample holder, and the pressure regulator.

18. The vacuum processing system according to claim 16, comprising a user interface unit for sending at least one of sample structure data and the sample position data to the control unit in response to user input.

19. The apparatus according to claim 15, wherein the duration, t_{RP}, of the refinement period, RP, is at least one of
at least 30 s,
at least 40 s,
at least 1 minute (min),
at least 2 min,
at least 5 min,
at least 8 min,
at least 10 min,
at least 12 min,
at least 15 min,
at least 18 min,
at least 20 min,
at least 30 min,
at least 45 min, and
at least 60 min.

20. The apparatus according to claim 15, wherein the refinement temperature range, ΔT, extends from at least one of
50° C. to 750° C.,
80° C. to 700° C.,
100° C. to 650° C.,
130° C. to 600° C., 160° C. to 550° C.,
180° C. to 520° C.,
200° C. to 500° C.,
220° C. to 480° C.,
240° C. to 460° C.,
260° C. to 440° C.,
280° C. to 420° C.,
300° C. to 400° C., and
320° C. to 380° C.
